(19) United States
(12) Patent Application Publication
(10) Pub. No.: US 2025/0167558 A1
(43) Pub. Date: May 22, 2025

(54) METHOD AND DEVICE FOR DETECTING ARCING IN ENERGY STORAGE SYSTEM, AND ENERGY STORAGE SYSTEM

(71) Applicant: Sungrow Power Supply Co., Ltd., Hefei (CN)

(72) Inventors: Kai Deng, Hefei (CN); Le Li, Hefei (CN); Qin Zhu, Hefei (CN); Xiaoyu Liu, Hefei (CN)

(73) Assignee: Sungrow Power Supply Co., Ltd., Hefei (CN)

(21) Appl. No.: 18/665,877

(22) Filed: May 16, 2024

(30) Foreign Application Priority Data
Nov. 20, 2023 (CN) 202311563329.4

(51) Int. Cl. H02J 3/38; H02H 1/00; H02J 3/32

(52) U.S. Cl. CPC H02J 3/381; H02H 1/0015; H02J 3/32; H02J 2300/26

(57) ABSTRACT

A method and a device for detecting arcing in an energy storage system, and an energy storage system are provided. The method includes: detecting an arcing feature in current of varying frequencies through a direct current bus of a power conversion system (PCS) unit, where the PCS unit is arranged in a PCS in the energy storage system; detecting a sudden change in port voltage of the PCS unit, in response to success in detecting the arcing feature; and determining that an electric arc occurs in a circuit where the PCS unit is arranged, in response to success in detecting the sudden change.

The present application claims priority to Chinese Patent Application No. 202311563329.4, filed on Nov. 20, 2023 with the China National Intellectual Property Administration, which is hereby incorporated by reference in its entirety.

### FIELD

The present disclosure relates to the technical field of circuit inspection, and in particular to an energy storage system, a method and a device for detecting arcing in the energy storage system.

### BACKGROUND

At present, an instrument transformer connected to a branch that performs Maximum Power Point Tracking (MPPT) in a photovoltaic system detects an electric arc in the photovoltaic system. It is determined that an electric arc occurs in the photovoltaic system when an arcing feature is detected in a frequency spectrum of current through the branch.

However, this solution is less accurate when applied to an energy storage system.

### SUMMARY

An energy storage system, a method and a device for detecting arcing in the energy storage system are provided according the present disclosure, to accurately detect an electric arc in the energy storage system.

The following technical solutions are provided according to the present disclosure.

A method for detecting arcing in an energy storage system is provided according to the present disclosure. The method includes: detecting an arcing feature in current of varying frequencies through a direct current bus of a power conversion system (PCS) unit, where the PCS unit is arranged in a PCS in the energy storage system; detecting a sudden change in port voltage of the PCS unit, in response to success in detecting the arcing feature; and determining that an electric arc occurs in a circuit where the PCS unit is arranged, in response to success in detecting the sudden change.

In an embodiment, the detecting the sudden change in the port voltage of the PCS unit includes: acquiring the port voltage of the PCS unit; calculating an absolute value of a difference in the port voltage between consecutive acquisitions; comparing the absolute value with a preset absolute threshold; and determining that the sudden change occurs in the port voltage of the PCS unit if the absolute value is greater than the preset absolute threshold.

In an embodiment, the detecting the sudden change in the port voltage of the PCS unit includes: collecting data on the port voltage of the PCS unit over a preset period of time, wherein the preset period of time ends at a present time instant; calculating an average rate of change in the port voltage of the PCS unit based on the data on the port voltage; comparing the average rate of change in the port voltage with a preset rate threshold; and determining that the sudden change occurs in the port voltage of the PCS unit if the average rate of change in the port voltage is greater than the preset rate threshold.

In an embodiment, the detecting the arcing feature in the current of varying frequencies through the direct current bus of the PCS unit includes: sampling the current through the direct current bus of the PCS unit; extracting an alternating current component from the sampled current; and detecting the arcing feature in the alternating current component.

In an embodiment, the detecting the arcing feature in the current of varying frequencies through the direct current bus of the PCS unit includes: performing Fast Fourier Transform (FFT) on the alternating current component, to obtain a frequency spectrum of the alternating current component; and detecting the arcing feature in the frequency spectrum.

In an embodiment, the method further includes: proceeding to the detecting an arcing feature in current of varying frequencies through the direct current bus of the PCS unit, in response to failure to detect the arcing feature.

In an embodiment, the method further includes: proceeding to the detecting an arcing feature in current of varying frequencies through the direct current bus of the PCS unit, in response to failure to detect the sudden change.

A device for detecting arcing in an energy storage system is provided according to the present disclosure. The device includes an arcing feature detection module, a port voltage monitor module, and a result determination module. The arcing feature detection module is configured to detect an arcing feature in current of varying frequencies through a direct current bus of a power conversion system (PCS) unit. The PCS unit is arranged in a PCS in the energy storage system. The port voltage monitor module is configured to detect a sudden change in port voltage of the PCS unit, in response to success in detecting the arcing feature in the current of varying frequencies through the direct current bus of the PCS unit. The result determination module is configured to determine that an electric arc occurs in a circuit where the PCS unit is arranged, in response to success in detecting the sudden change.

A device for detecting arcing in an energy storage system is provided according to the present disclosure. The device includes at least one processor and a memory. The memory is communicatively connected to the at least one processor and stores instructions executable by the at least one processor, for detecting an arcing feature in current of varying frequencies through a direct current bus of a power conversion system (PCS) unit, where the PCS unit is arranged in a PCS in the energy storage system; detecting a sudden change in port voltage of the PCS unit, in response to success in detecting the arcing feature; and determining that an electric arc occurs in a circuit where the PCS unit is arranged, in response to success in detecting the sudden change.

An energy storage system is provided according to the present disclosure. The energy storage system includes a local controller (LC), a power conversion system (PCS), and at least one battery cluster. The PCS includes at least one PCS unit. The battery cluster is connected to a direct current side of the PCS unit through a direct current bus. The direct current side of the PCS unit is connected to at least one battery cluster. The LC is communicatively connected to the at least one PCS unit and is configured to detect an electric arc in the energy storage system.

The technical solutions according to the present disclosure have the following beneficial effects.

According to the conventional technology, it is determined that an electric arc occurs in a circuit where the PCS unit is arranged once an arcing feature is detected in current of varying frequencies through the direct current bus of the PCS unit. However, with the technical solutions according to the present disclosure, detecting a sudden change in port voltage of the PCS unit if an arcing feature is detected in current of varying frequencies through the direct current bus of the PCS unit. It is determined that an electric arc occurs in a circuit where the PCS unit is arranged when a sudden change is detected in the port voltage of the PCS unit. In this way, accuracy of detecting an electric arc can be improved.

### BRIEF DESCRIPTION OF THE DRAWINGS

In order to more clearly describe the technical solutions in the embodiments of the present disclosure or the technical solutions in the conventional technology, drawings to be used in the description of the embodiments of the present disclosure or the conventional technology are briefly described hereinafter. It is apparent that the drawings described below are merely used for illustrating the embodiments of the present disclosure, and those skilled in the art can obtain other drawings according to the provided drawings without any creative effort.

FIG. 1 is a schematic structural diagram illustrating an energy storage system according to an embodiment of the present disclosure;

FIG. 2 is a flowchart illustrating a method for detecting arcing in an energy storage system according to an embodiment of the present disclosure;

FIG. 3 is a schematic diagram illustrating detection of an electric arc in an energy storage system according to an embodiment of the present disclosure;

FIG. 4 is a flowchart illustrating the method for detecting arcing in an energy storage system according to another embodiment of the present disclosure;

FIG. 5 is a schematic structural diagram illustrating a device for detecting arcing in an energy storage system according to an embodiment of the present disclosure; and

FIG. 6 is a schematic structural diagram illustrating the device for detecting arcing in an energy storage system according to an embodiment of the present disclosure.

### DETAILED DESCRIPTION OF EMBODIMENTS

Technical solutions of embodiments of the present disclosure are described clearly and completely below in conjunction with the drawings of the embodiments of the present disclosure. Apparently, the embodiments described below are only some rather than all of the embodiments of the present disclosure. Any other embodiments obtained by those skilled in the art based on the embodiments in the present disclosure without any creative effort fall within the protection scope of the present disclosure.

At present, an instrument transformer connected to a branch that performs MPPT in a photovoltaic system detects an electric arc in the photovoltaic system. It is determined that an electric arc occurs in the photovoltaic system when an arcing feature is detected in a frequency spectrum of current through the branch, which is up to 30 A.

The photovoltaic system is characterized by low voltage and small current. Therefore, the frequency spectrum of current through the photovoltaic system in case of arcing is significantly different from that in case of no arcing at high frequencies, for example, 16 kHz, 32 kHz and the like. The switching frequency is 16 kHz. Current with a feature frequency band greater than 16 kHz is strong on anti-interference ability and is easily identifiable. Therefore, the existing solution is highly accurate when applied to a photovoltaic system.

However, the existing energy storage system supplies 1500V voltage and more than 200 A current. That is, the existing energy storage system is characterized by high voltage and large current. Therefore, the frequency spectrum of current through the energy storage system in case of arcing is slightly different from that in case of no arcing. In addition, significant difference lies in low frequencies from 2 kHz to 3 kHz, which are common and weak in anti-interference ability, imposing difficulty in analyzing and extracting arcing feature by software. That is, the existing solution is less accurate when applied to an energy storage system.

In view of this, an energy storage system, a method and a device for detecting arcing in the energy storage system are provided according the present disclosure, to accurately detect an electric arc in the energy storage system.

Technical solutions according the present disclosure are described in detail below in conjunction with the drawings.

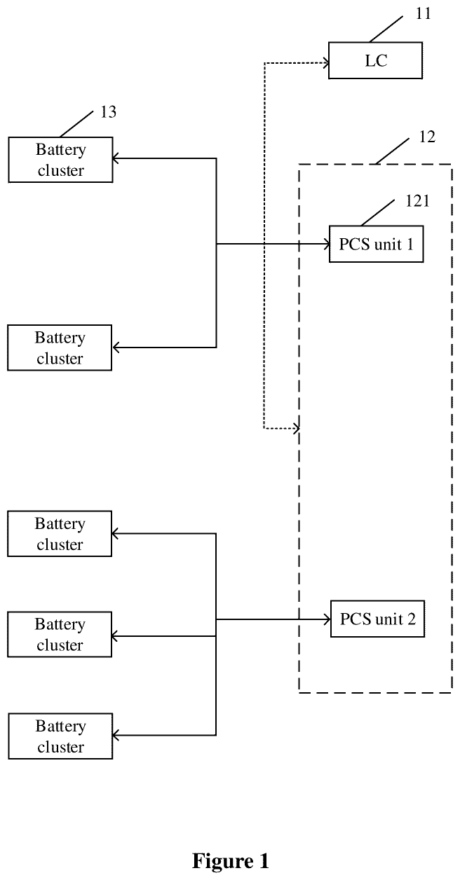

FIG. 1 is a schematic structural diagram illustrating the energy storage system according to an embodiment of the present disclosure. As illustrated in FIG. 1, the energy storage system includes a local controller LC 11, a power conversion system PCS 12, and at least one battery cluster 13 (for example, four battery clusters as illustrated in FIG. 1).

The PCS 12 includes at least one PCS unit 121 (for example, two PCS units as illustrated in FIG. 1).

The battery cluster 13 is connected to a direct current side of the PCS unit 121 through a direct current bus. The direct current side of the PCS unit 121 is connected to at least one battery cluster 13. As shown in FIG. 1, the direct current side of one PCS unit 121 is connected to two battery clusters 13 and the direct current side of the other PCS unit 121 is connected to three battery clusters 13. Battery clusters 13 connected to the direct current side of the same PCS unit 121 are connected in parallel.

The LC 11 is communicatively connected to all the PCS units 121.

The LC 11 is configured to detect, for each of the PCS units 121, an electric arc in a circuit where the PCS unit is arranged.

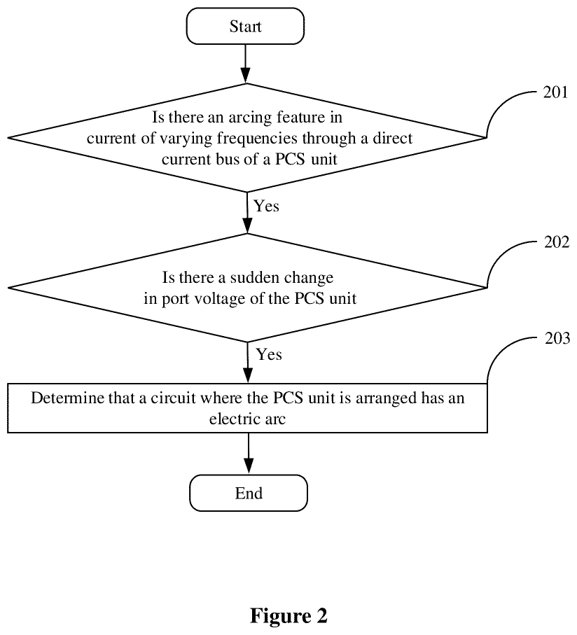

FIG. 2 is a flowchart illustrating the method for detecting arcing in the energy storage system according to an embodiment of the present disclosure. As illustrated in FIG. 2, the method includes the following steps 201 to 203.

In step 201, it is detected whether there is an arcing feature in current of varying frequencies through a direct current bus of the PCS unit. The method proceeds to step 202 if an arcing feature is detected in the current of varying frequencies through the direct current bus of the PCS unit.

The arcing feature indicates frequency, where a difference between the frequency indicated by the arcing feature and a conference frequency is greater than a preset frequency difference threshold.

The PCS unit is arranged in the PCS of the energy storage system. The method for detecting arcing according to the present disclosure is applied to any one of multiple PCS units in the energy storage system.

In step 202, it is detected whether there is a sudden change in port voltage of the PCS unit. The method proceeds to step 203 if a sudden change is detected in the port voltage of the PCS unit.

In step 203, it is determined that an electric arc occurs in a circuit where the PCS unit is arranged.

In the energy storage system, the battery cluster serves as a voltage source, and thus is different from a photovoltaic panel (serving as a current source). The battery cluster outputs constant voltage even if arcing occurs. In view of this, a sudden change is resulted from impedance in case of arcing.

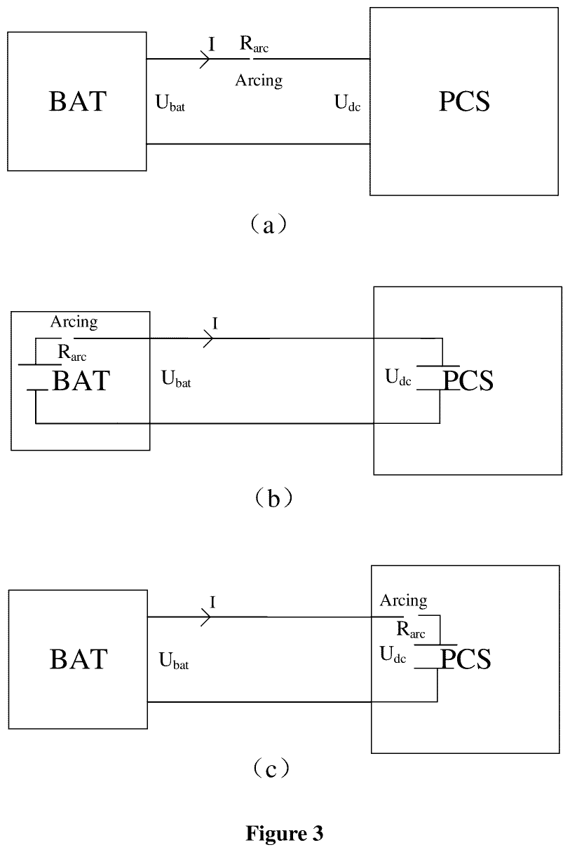

FIG. 3 is a schematic diagram illustrating detection of an electric arc in the energy storage system according to an embodiment of the present disclosure. As illustrated in FIG. 3, the following equation (1) can be derived from a circuit where a battery cluster is being charged in case of arcing.

U_{dc}=U_{bat}−I*R_{arc} (1)

In the equation (1), U_{dc} represents the port voltage of the PCS unit, U_{bat} represents the voltage outputted by the battery cluster, I represents the current through the circuit, and R_{arc} represents the impedance resulted from the electrical arc.

The following equation (2) can be derived in case of no arcing.

U_{dc}=U_{bat} (2)

It can be seen from equation (1) and equation (2) that there is certainly a sudden change in the port voltage of the PCS unit regardless of where exactly the arcing occurs in the circuit. In practice, the sudden change in the port voltage of the PCS unit approximates 70V. Therefore, it is determined that an electric arc occurs when a sudden change is detected in the port voltage of the PCS unit.

It should be noted that in FIG. 3, BAT, i.e., Battery, sometimes is abbreviated as BT and refers to a battery. BAT refers to a battery cluster herein. In FIG. 3, diagram (a) illustrates the case when an electric arc occurs between the battery cluster and the PCS unit, for example, in a branch of the positive electrode of the battery cluster or in a branch of the negative electrode of the battery cluster. Diagram (b) illustrates the case when an electric arc occurs inside the battery cluster, for example, between cells in the battery cluster. Diagram (c) illustrates the case when an electric arc occurs inside the PCS unit.

In the existing solution, it is determined that an electric arc occurs in a circuit where the PCS unit is arranged once an arcing feature is detected in current of varying frequencies through the direct current bus of the PCS unit. However, with the technical solutions according to the present disclosure, detecting a sudden change in port voltage of the PCS unit if an arcing feature is detected in current of varying frequencies through the direct current bus of the PCS unit. It is determined that an electric arc occurs in a circuit where the PCS unit is arranged when a sudden change is detected in the port voltage of the PCS unit. In this way, accuracy of detecting an electric arc can be improved.

In some embodiment of the present disclosure, the detection of the sudden change in the port voltage of the PCS unit in step 202 includes the following steps (1) to (4).

In (1), the port voltage of the PCS unit is acquired.

In (2), an absolute value of a difference in the port voltage between consecutive acquisitions is calculated.

In (3), the absolute value compared with a preset absolute threshold.

The preset absolute threshold is set by those skilled in the art according to actual situations. For example, the preset absolute threshold is set to 70V.

In (4), it is determined that the sudden change occurs in the port voltage of the PCS unit if the absolute value is greater than the preset absolute threshold.

In this solution, detection of the sudden change in the port voltage of the PCS unit can be implemented by simply comparing the absolute value of the difference in the port voltage between consecutive acquisitions with the preset absolute threshold. In this way, the detection of arcing can be implemented quickly by virtue of simple calculation.

In some embodiments of the present disclosure, the detection of the sudden change in the port voltage of the PCS unit in step 202 includes the following steps (1) to (4).

In (1), data on the port voltage of the PCS unit is collected over a preset period of time.

Here, the preset period of time ends at a present time instant. In addition, a length of the preset period of time is set by those skilled in the art according to actual situations. For example, the preset period of time is set to 10 minutes.

In (2), an average rate of change in the port voltage of the PCS unit is calculated based on the data on the port voltage.

In an example, the data on the port voltage includes a port voltage 1, a port voltage 2, a port voltage 3 and a port voltage 4. To calculate the average rate of change in the port voltage of the PCS unit, a first absolute value of a difference between the port voltage 1 and the port voltage 2, a second absolute value of a difference between the port voltage 2 and the port voltage 3, and a third absolute value of a difference between the port voltage 3 and the port voltage 4 are calculated first, and then an average of the first to three absolute values is calculated to obtain the average rate of change in the port voltage.

In (3), the average rate of change in the port voltage is compared with a preset rate threshold.

In (4), it is determined that the sudden change occurs in the port voltage of the PCS unit if the average rate of change in the port voltage is greater than the preset rate threshold.

In this solution, accurate detection of the sudden change in the port voltage of the PCS unit can be implemented by simply comparing the average rate of change in the port voltage of the PCS unit over the preset period of time with the preset rate threshold. In this way, the detection of arcing can be implemented quickly by virtue of simple calculation. In this way, accuracy of detecting an electric arc can be further improved.

In some embodiments of the present disclosure, the detection of the arcing feature in the current of varying frequencies through the direct current bus of the PCS unit includes the following steps (1) to (3).

In (1), the current through the direct current bus of the PCS unit is sampled.

In (2), an alternating current component is extracted from the sampled current.

In (3), it is detected whether there is the arcing feature in the alternating current component.

In some embodiments of the present disclosure, the detection of the arcing feature in alternating current component includes the following steps (1) to (2).

In (1), Fast Fourier Transform (FFT) is performed on the alternating current component to obtain a frequency spectrum of the alternating current component.

In (2), it is detected whether there is the arcing feature in the frequency spectrum.

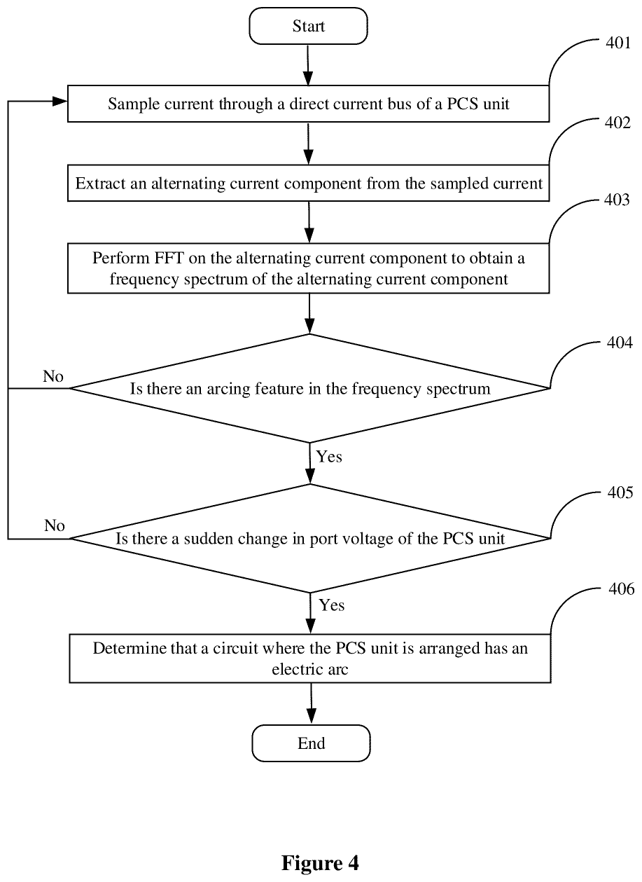

FIG. 4 is a flowchart illustrating the method for detecting arcing in the energy storage system according to another embodiment of the present disclosure. As illustrated in FIG. 4, the method includes the following steps 401 to 406.

In step 401, the current through the direct current bus of the PCS unit is sampled.

In step 402, an alternating current component is extracted from the sampled current.

In step 403, FFT is performed on the alternating current component to obtain a frequency spectrum of the alternating current component.

In step 404, it is detected whether there is an arcing feature in the frequency spectrum. The method proceeds to step 405 if an arcing feature is detected in the frequency spectrum. Otherwise, the method returns to step 401.

In step 405, it is detected whether there is a sudden change in port voltage of the PCS unit. The method proceeds to step 406 a sudden change is detected in the port voltage of the PCS unit. Otherwise, the method returns to step 401.

In step 406, it is determined that an electric arc occurs in a circuit where the PCS unit is arranged.

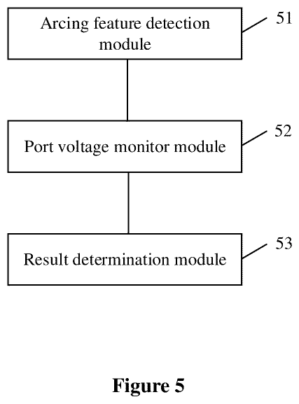

Based on the same inventive concept, a device for detecting arcing in an energy storage system is further provided according to the present disclosure. FIG. 5 is a schematic structural diagram illustrating the device for detecting arcing in an energy storage system according to an embodiment of the present disclosure. As illustrated in FIG. 5, the device includes an arcing feature detection module 51, a port voltage monitor module 52, and a result determination module 53.

The arcing feature detection module 51 is configured to determine whether there is an arcing feature in current of varying frequencies flowing through a direct current bus of a PCS unit. The PCS unit is a unit in a PCS of the energy storage system.

The port voltage monitor module 52 is configured to determine whether there is a sudden change in port voltage of the PCS unit if there is the arcing feature in the current frequencies of the current flowing through the direct current bus of the PCS unit.

The result determination module 53 is configured to determine that an electric arc is generated in a loop where the PCS unit is arranged if the port voltage of the PCS unit changes sharply.

In an embodiment, the port voltage monitor module 52 is configured to: (1) acquire the port voltage of the PCS unit; (2) calculate an absolute value of a difference in the port voltage between consecutive acquisitions; (3) compare the absolute value with a preset absolute threshold; and (4) determine that the sudden change occurs in the port voltage of the PCS unit if the absolute value is greater than the preset absolute threshold.

In an embodiment, the port voltage monitor module 52 is configured to: (1) collect data on the port voltage of the PCS unit over a preset period of time, where the preset period of time ends at a present time instant; (2) calculate an average rate of change in the port voltage of the PCS unit based on the data on the port voltage; (3) compare the average rate of change in the port voltage with a preset rate threshold; and (4) determine that the sudden change occurs in the port voltage of the PCS unit if the average rate of change in the port voltage is greater than the preset rate threshold.

In an embodiment, the arcing feature detection module 51 includes a current acquisition unit, an alternating current extraction unit and an arcing feature detection unit. The current acquisition unit is configured to the current through the direct current bus of the PCS unit. The alternating current extraction unit is configured to extract an alternating current component from the sampled current. The arcing feature detection unit is configured to detect the arcing feature in the alternating current component.

In an embodiment, the arcing feature detection unit is configured to: (1) perform FFT on the alternating current component, to obtain a frequency spectrum of the alternating current component; and (2) detect the arcing feature in the frequency spectrum.

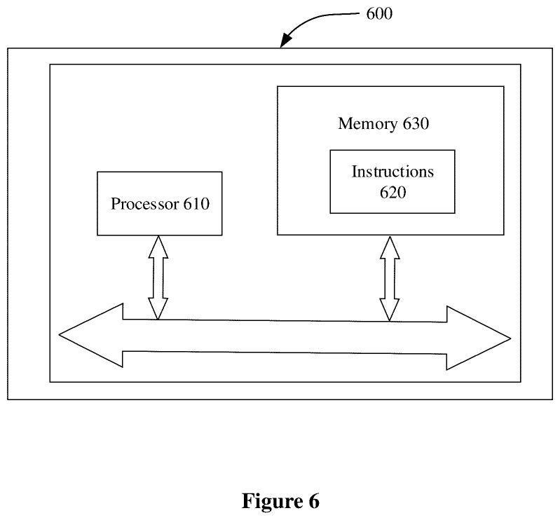

Based on the same inventive concept, a device for detecting arcing in an energy storage system is further provided according to the present disclosure. FIG. 6 is a schematic structural diagram illustrating the device for detecting arcing in an energy storage system according to an embodiment of the present disclosure. As illustrated in FIG. 6, a device 600 includes at least one processor 610 and a memory 630 communicatively connected to the at least one processor 610. The memory 630 stores instructions 620 executable by the at least one processor 610. The instructions 620, when executed by the at least one processor 610, cause the at least one processor 610 to implement the method for detecting arcing in an energy storage system as described above.

The above method embodiments are described as combinations of a series of actions for the sake of brevity. However, those skilled in the art should understand that the present disclosure is not limited to the described order of the actions. Instead, some of the steps may be performed in a different order or simultaneously according to the present disclosure. In addition, those skilled in the art should also understand that the embodiments described in the specification are preferred embodiments, and the actions and modules described are unnecessary for the present disclosure.

It should be noted that the embodiments in this specification are described in a progressive way, each of the embodiments emphasizes the differences from others, and the same or similar parts among the embodiments can be referred to each other. Since the device disclosed in the embodiments is basically similar to the method therein, the description of the device is relatively simple, and for relevant matters, one may refer to the description of the method embodiments.

Steps in the embodiments of the present disclosure can be performed in a different order, merged, and deleted. Technical features disclosed in the embodiments can be replaced or combined.

Modules and sub-modules in the device and the terminal in the embodiments of the present disclosure can be merged, divided, and deleted according to actual needs.

It should be noted that the terminal, the device, and the method disclosed in the embodiments of the present disclosure can be implemented in other manners. For example, the terminal embodiment described above is only for illustration. For example, modules or sub-modules are divided only according to logical functions, and the modules or sub-modules are divided in other manner in practice. For example, multiple sub-modules or modules are combined or integrated into another module, or some features are ignored or not implemented. In addition, the illustrated or described mutual coupling, direct coupling, or connection communication is indirect coupling or communication connection via some interfaces, devices or modules, which is electrical, mechanical or in other form.

The modules or sub-modules described as separated components may be or may not be physically separated. Components described as modules or sub-modules may be or may not be physical modules or sub-modules. That is, the components are arranged in a same place, or distributed in multiple network modules or sub-modules. Some or all of the modules or sub-modules are selected according to actual needs to realize the purpose of the solutions according to the embodiments.

In addition, various functional modules or sub-modules in the embodiments of the present disclosure are integrated in a same processing module. Alternatively, the various functional modules or sub-modules are physically separated. Alternatively, two or more modules or sub-modules are integrated in a same module. The integrated modules or sub-modules are implemented by hardware, software function modules or sub-modules.

Those skilled in the art should further understand that units and algorithm steps in examples described in conjunction with the embodiments disclosed herein can be implemented by electronic hardware, computer software or a combination thereof. In order to clearly describe interchangeability of the hardware and the software, the composition and steps in the examples are generally described above based on functions. Whether these functions are implemented by hardware or software depends on specific applications and design constraints for the technical solutions. Those skilled in the art use different methods for different applications to implement the described functions, and such implementation should not be considered as beyond the scope of the present disclosure.

Steps of the methods or algorithms described in conjunction with the embodiments disclosed herein are directly implemented by hardware, a software unit executed by a processor or a combination thereof. The software unit is arranged in a random access memory (RAM), an internal memory, a read-only memory (ROM), an electrically programmable ROM, an electrically erasable programmable ROM, a register, a hard disk, a removable disk, a CD-ROM or any other form of storage medium known in the art.

It should be further noted that relation terms such as “first” and “second” herein are only used to distinguish one entity or operation from another entity or operation, and does not necessarily require or imply that there is an actual relation or sequence between these entities or operations. Moreover, terms “comprise”, “include”, or any other variants thereof are intended to encompass a non-exclusive inclusion, such that a process, method, article, or device including a series of elements includes not only those elements but also other elements that are not explicitly listed, or elements that are inherent to such process, method, article, or device. Unless explicitly limited, the statement “including a . . . ” does not exclude the case that other similar elements exist in the process, method, article or device including the enumerated elements.

Those skilled in the art can implement or practice the present disclosure based on the above description of the disclosed embodiments. Various modifications to these embodiments are obvious to those skilled in the art, and the general concept defined herein can be implemented in other embodiments without departing from the spirit and scope of the present disclosure. Therefore, the present disclosure should not be limited to the embodiments disclosed herein, but has the widest scope in accordance to the principle and the novel features disclosed herein.

1. A method for detecting arcing in an energy storage system, comprising:
detecting an arcing feature in current of varying frequencies through a direct current bus of a power conversion system (PCS) unit, wherein the PCS unit is arranged in a PCS in the energy storage system;
detecting a sudden change in port voltage of the PCS unit, in response to success in detecting the arcing feature; and
determining that an electric arc occurs in a circuit where the PCS unit is arranged, in response to success in detecting the sudden change.

2. The method according to claim 1, wherein the detecting the sudden change in the port voltage of the PCS unit comprises:
acquiring the port voltage of the PCS unit;
calculating an absolute value of a difference in the port voltage between consecutive acquisitions;
comparing the absolute value with a preset absolute threshold; and
determining that the sudden change occurs in the port voltage of the PCS unit if the absolute value is greater than the preset absolute threshold.

3. The method according to claim 1, where the detecting the sudden change in the port voltage of the PCS unit comprises:
collecting data on the port voltage of the PCS unit over a preset period of time, wherein the preset period of time ends at a present time instant;
calculating an average rate of change in the port voltage of the PCS unit based on the data on the port voltage;
comparing the average rate of change in the port voltage with a preset rate threshold; and
determining that the sudden change occurs in the port voltage of the PCS unit if the average rate of change in the port voltage is greater than the preset rate threshold.

4. The method according to claim 1, wherein the detecting the arcing feature in the current of varying frequencies through the direct current bus of the PCS unit comprises:
sampling the current through the direct current bus of the PCS unit;
extracting an alternating current component from the sampled current; and
detecting the arcing feature in the alternating current component.

5. The method according to claim 4, wherein the detecting the arcing feature in the alternating current component comprises:
performing Fast Fourier Transform (FFT) on the alternating current component, to obtain a frequency spectrum of the alternating current component; and
detecting the arcing feature in the frequency spectrum.

6. The method according to claim 1, further comprising:
proceeding to the detecting an arcing feature in current of varying frequencies through the direct current bus of the PCS unit, in response to failure to detect the arcing feature.

7. The method according to claim 1, further comprising:
proceeding to the detecting an arcing feature in current of varying frequencies through the direct current bus of the PCS unit, in response to failure to detect the sudden change.

8. A device for detecting arcing for an energy storage system, comprising:
an arcing feature detection module configured to detect an arcing feature in current of varying frequencies through a direct current bus of a power conversion system (PCS) unit, wherein the PCS unit is arranged in a PCS in the energy storage system;
a port voltage monitor module configured to detect a sudden change in port voltage of the PCS unit, in response to success in detecting the arcing feature in the current of varying frequencies through the direct current bus of the PCS unit; and
a result determination module configured to determine that an electric arc occurs in a circuit where the PCS unit is arranged, in response to success in detecting the sudden change.

9. A device for detecting arcing for an energy storage system, comprising:
at least one processor; and
a memory communicatively connected to the at least one processor and storing instructions executable by the at least one processor for:
detecting an arcing feature in current of varying frequencies through a direct current bus of a power conversion system (PCS) unit, wherein the PCS unit is arranged in a PCS in the energy storage system;
detecting a sudden change in port voltage of the PCS unit, in response to success in detecting the arcing feature; and
determining that an electric arc occurs in a circuit where the PCS unit is arranged, in response to success in detecting the sudden change.

10. An energy storage system, comprising:
a local controller (LC);
a power conversion system (PCS); and
a battery cluster, wherein
the PCS comprises a PCS unit;
the battery cluster is connected to a direct current side of the PCS unit through a direct current bus;
the LC is communicatively connected to the PCS unit; and
the LC is configured to perform the method according to claim 1.
